(19) United States
(12) Patent Application Publication
(10) Pub. No.: US 2011/0007771 A1
(43) Pub. Date: Jan. 13, 2011

(54) SEMICONDUCTOR LASER APPARATUS, METHOD OF MANUFACTURING THE SAME AND OPTICAL APPARATUS

(75) Inventors: Yasuyuki BESSHO, Uji-shi (JP); Koji GONSUI, Iwami-gun (JP); Gen SHIMIZU, Tottori-shi (JP); Daiki MIHASHI, Tottori-shi (JP); Kiyoshi OOTA, Neyagawa-shi (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi-shi (JP)

(21) Appl. No.: 12/831,000

(22) Filed: Jul. 6, 2010

(30) Foreign Application Priority Data
Jul. 8, 2009 (JP) 2009-162133

(51) Int. Cl. H01S 5/40; H01S 5/323; H01L 21/50

(52) U.S. Cl. 372/50.121; 372/44.01; 438/28; 257/E21.499

(57) ABSTRACT

This semiconductor laser apparatus includes a support member having a main surface, a first semiconductor laser device bonded onto the main surface through a first bonding layer and a second semiconductor laser device bonded onto the main surface through a second bonding layer to be adjacent to the first semiconductor laser device. The melting point of the second bonding layer is lower than that of the first bonding layer, and a first height from the main surface to a fourth surface of the second semiconductor laser device is larger than a second height from the main surface to a second surface of the first semiconductor laser device.

### CROSS-REFERENCE TO RELATED APPLICATION

The priority application number JP2009-162133, Semiconductor Laser Apparatus, Method of Manufacturing the Same, Optical Pickup and Optical Apparatus, Jul. 8, 2009, Yasuyuki Bessho et al, upon which this patent application is based is hereby incorporated by reference.

### BACKGROUND OF THE INVENTION

1. Field of the Invention

The present invention relates to a semiconductor laser apparatus, a method of manufacturing the same and an optical apparatus, and more particularly, it relates to a semiconductor laser apparatus loaded with a plurality of hybrid integrated semiconductor laser devices, a method of manufacturing the same and an optical apparatus employing the same.

2. Description of the Background Art

An optical pickup comprising a semiconductor laser apparatus, optical components such as a lens, a beam splitter (BS) etc., a photodetector and so on is employed in an optical disc device for at least either recording information in an optical disc such as a CD (Compact Disc), a DVD (Digital Versatile Disc) or a BD (Blu-ray Disc®) or reproducing the information in general. A hybrid integrated semiconductor laser apparatus loaded with a plurality of semiconductor laser devices emitting different lasing wavelengths is known as a semiconductor laser apparatus for a compatible optical pickup capable of at least either recording in the aforementioned plurality of types of optical discs or reproduction of these optical discs by a single optical pickup, as disclosed in Japanese Patent Laying-Open Nos. 2000-222766 and 2000-268387, for example.

The aforementioned Japanese Patent Laying-Open No. 2000-222766 discloses a semiconductor laser apparatus loaded with two semiconductor laser devices having different heights, being adjacent to each other on a submount.

The aforementioned Japanese Patent Laying-Open No. 2000-268387 discloses a semiconductor laser apparatus in which two semiconductor laser devices are bonded onto a substrate to be adjacent to each other using different types of solder having different melting points from each other. In a method of manufacturing this conventional semiconductor laser apparatus, a first semiconductor laser device is bonded onto the substrate using first solder. Thereafter, a second semiconductor laser device is heated to a temperature lower than the melting point of the first solder and higher than the melting point of second solder to be bonded onto the substrate using the second solder having a lower melting point than the first solder.

In a manufacturing process of each of the conventional semiconductor laser apparatuses, each semiconductor laser device is held by vacuum-absorbing an upper surface thereof using a fixture such as a collet and is heated in a state pressed on the substrate through solder to be bonded onto the substrate.

In the aforementioned manufacturing process of each of the conventional semiconductor laser apparatuses, however, a width of an end of the fixture becomes larger than that of the semiconductor laser device when the semiconductor laser device is downsized, and hence the end of the fixture disadvantageously easily comes into contact with the first bonded semiconductor laser device when the two semiconductor laser devices are bonded to be adjacent to each other. In particular, when the semiconductor laser apparatus disclosed in Japanese Patent Laying-Open No. 2000-222766 is manufactured, the aforementioned contact of the fixture easily occurs in a case where the higher semiconductor laser device is bonded to the submount and the lower semiconductor laser device is thereafter bonded to the submount. Consequently, the first bonded semiconductor laser device is disadvantageously easily damaged, and the later bonded semiconductor laser device is disadvantageously easily poorly bonded onto the submount. The solder for the first bonded semiconductor laser device is remelted by heat treatment in bonding the later bonded semiconductor laser device, and hence the first bonded semiconductor laser device is disadvantageously easily displaced.

Further, when the two semiconductor laser devices are separated from each other in order not to bring into contact with the fixture, regions from which laser beams are emitted (light-emitting points), of the two semiconductor laser devices are separated from each other, and hence it is disadvantageously difficult to downsize optical components, perform alignment and so on when forming an optical pickup.

### SUMMARY OF THE INVENTION

A semiconductor laser apparatus according to a first aspect of the present invention comprises a support member having a main surface, a first semiconductor laser device bonded onto the main surface through a first bonding layer and a second semiconductor laser device bonded onto the main surface through a second bonding layer, wherein the first semiconductor laser device has a first surface and a second surface opposite to the first surface, the second semiconductor laser device has a third surface and a fourth surface opposite to the third surface, the second semiconductor laser device is arranged to be adjacent to the first semiconductor laser device, the first surface of the first semiconductor laser device is bonded onto the main surface, the third surface of the second semiconductor laser device is bonded onto the main surface, the melting point of the second bonding layer is lower than that of the first bonding layer, and a first height from the main surface to the fourth surface is larger than a second height from the main surface to the second surface.

In the semiconductor laser apparatus according to the first aspect of the present invention, as hereinabove described, a height of the second semiconductor laser device from the main surface of the support member (first height from the main surface to the fourth surface) is larger than a height of the first semiconductor laser device from the main surface of the support member (second height from the main surface to the second surface), and hence the second semiconductor laser device can be easily bonded also after bonding the first semiconductor laser device. When each semiconductor laser device is bonded using a fixture, for example, a fixture used when bonding the second semiconductor laser device can be inhibited from being in contact with the first bonded first semiconductor laser device. Thus, the first semiconductor laser device can be inhibited from being damaged and the second semiconductor laser device can be excellently bonded onto the support member, and hence poor bonding of the second semiconductor laser device is unlikely to occur.

The melting point of the second bonding layer employed for bonding the second semiconductor laser device is lower than that of the first bonding layer employed for bonding the first semiconductor laser device, and hence heat treatment in bonding the second semiconductor laser device can be performed at a lower temperature than the melting point of the first bonding layer. Thus, also in a case where the first semiconductor laser device is first bonded, for example, the first bonding layer can be inhibited from being remelted when bonding the second semiconductor laser device, whereby the first bonded first semiconductor laser device can be inhibited from displacement. Consequently, the semiconductor laser apparatus with high reliability and excellent yield can be obtained in the first aspect of the present invention.

The first and second semiconductor laser devices can be arranged to be adjacent to each other, and hence regions from which laser beams are emitted (light-emitting points) thereof can be brought close to each other. Thus, optical components can be easily downsized, alignment can be easily performed and so on when mounting the semiconductor laser apparatus on an optical apparatus such as an optical pickup.

The heights of the first semiconductor laser device and the second semiconductor laser device are different from each other, and hence the first semiconductor laser device and the second semiconductor laser device can be easily identified. The front and the back of the semiconductor laser apparatus can be easily identified, for example. Thus, the semiconductor laser apparatus can be easily mounted on the optical apparatus, and an arrangement of a peripheral optical system or the like in the optical apparatus can be easily performed without a mistake.

The melting points of the first and second bonding layers formed on lower sides of the first and second semiconductor laser devices are different from each other, and hence only the second bonding layer can be remelted to adjust a position of the second semiconductor laser device also when the first semiconductor laser device is first bonded, for example. In this case, the first bonding layer can be inhibited from being remelted without excessively increasing a heat treatment temperature, and positions of the light-emitting points of the first and second semiconductor laser devices can be precisely controlled.

In the aforementioned semiconductor laser apparatus according to the first aspect, the first semiconductor laser device preferably has a first semiconductor substrate on a side closer to the second surface and a first semiconductor device layer on a side closer to the first surface, and the second semiconductor laser device preferably has a second semiconductor substrate on a side closer to the fourth surface and a second semiconductor device layer on a side closer to the third surface. According to this structure, the first semiconductor laser device and the second semiconductor laser device are bonded such that sides provided with the first semiconductor device layer and the second semiconductor device layer with respect to the first semiconductor substrate and the second semiconductor substrate respectively are close to the support member. In other words, the first semiconductor laser device and the second semiconductor laser device are mounted in a junction-down manner with respect to the support member, and hence heat can be efficiently radiated from the first semiconductor device layer and the second semiconductor device layer which are heat generation sources toward the support member. Consequently, temperature characteristics and reliability of the first semiconductor laser device and the second semiconductor laser device can be improved.

Thicknesses of the first semiconductor device layer and the second semiconductor device layer are controlled, whereby heights of the light-emitting points of the first semiconductor laser device and the second semiconductor laser device from the main surface of the support member can be easily equalized with each other. Thus, a position of each of the light-emitting points can be precisely controlled when this semiconductor laser apparatus is employed as a light source of the optical apparatus or the like.

In the aforementioned semiconductor laser apparatus according to the first aspect, a thickness of the first bonding layer and a thickness of the second bonding layer are preferably substantially equal to each other. According to this structure, the height of each of the semiconductor laser devices from the main surface of the support member can be easily controlled by a thickness of each of the semiconductor laser devices. Further, heights from the main surface of the support member to the light-emitting points of the semiconductor laser devices can be easily rendered uniform.

In the aforementioned semiconductor laser apparatus according to the first aspect, the support member is preferably a heat radiation substrate. According to this structure, heat generated in the first and second semiconductor laser devices can be efficiently radiated through the support member, which is a heat radiation substrate. Especially when the semiconductor laser devices are mounted in the junction-down manner with respect to the support member, temperature characteristics and reliability of the semiconductor laser devices can be improved.

In the aforementioned semiconductor laser apparatus according to the first aspect, an interval between the first semiconductor laser device and the second semiconductor laser device is preferably narrow on a side closer to the main surface and preferably becomes wider with increasing distance from the main surface. According to this structure, the light-emitting points of the first and second semiconductor laser devices can be easily brought close to each other.

In this case, a cross section of at least either the first semiconductor laser device or the second semiconductor laser device is preferably substantially parallelogram shaped. According to this structure, the semiconductor laser apparatus in which the interval between the first semiconductor laser device and the second semiconductor laser device is narrow on the side closer to the main surface and becomes wider with increasing distance from the main surface can be easily obtained.

A method of manufacturing a semiconductor laser apparatus according to a second aspect of the present invention comprises steps of bonding a first semiconductor laser device onto a main surface of a support member through a first bonding layer and bonding a second semiconductor laser device onto the main surface through a second bonding layer to be adjacent to the first semiconductor laser device after the step of bonding the first semiconductor laser device, wherein the first semiconductor laser device has a first surface and a second surface opposite to the first surface, the second semiconductor laser device has a third surface and a fourth surface opposite to the third surface, the first surface of the first semiconductor laser device is bonded onto the main surface, the third surface of the second semiconductor laser device is bonded onto the main surface, and a first height from the main surface to the fourth surface is larger than a second height from the main surface to the second surface.

In the method of manufacturing a semiconductor laser apparatus according to the second aspect of the present invention, as hereinabove described, a height of the second semiconductor laser device from the main surface of the support member (first height from the main surface to the fourth surface) is larger than a height of the first semiconductor laser device from the main surface of the support member (second height from the main surface to the second surface), and hence the second semiconductor laser device can be easily bonded also after bonding the first semiconductor laser device. When each semiconductor laser device is bonded using a fixture, for example, a fixture used when bonding the second semiconductor laser device can be inhibited from being in contact with the first bonded first semiconductor laser device. Thus, the first semiconductor laser device can be inhibited from being damaged and the second semiconductor laser device can be excellently bonded onto the support member, and hence poor bonding of the second semiconductor laser device is unlikely to occur. Consequently, in the method of manufacturing a semiconductor laser apparatus according to the second aspect of the present invention, a semiconductor laser apparatus with high reliability and excellent yield can be easily manufactured.

The first and second semiconductor laser devices can be arranged to be adjacent to each other, and hence regions from which laser beams are emitted (light-emitting points) thereof can be brought close to each other. Thus, a semiconductor laser apparatus capable of being employed as an optical apparatus such as a small optical pickup allowing easy downsizing of optical components and easy alignment can be easily manufactured.

The heights of the first semiconductor laser device and the second semiconductor laser device are different from each other, and hence the first semiconductor laser device and the second semiconductor laser device can be easily identified. The front and the back of the semiconductor laser apparatus can be easily identified, for example. Thus, the semiconductor laser apparatus capable of being easily mounted on the optical apparatus or the like and enabling an easy arrangement of a peripheral optical system or the like in the optical apparatus without a mistake can be manufactured.

When the melting points of the first and second bonding layers formed on lower sides of the first and second semiconductor laser devices are different from each other, only the second bonding layer can be remelted to adjust a position of the second semiconductor laser device also in a case where the first semiconductor laser device is first bonded, for example. In this case, the first bonding layer can be inhibited from being remelted without excessively increasing a heat treatment temperature, and positions of the light-emitting points of the first and second semiconductor laser devices can be precisely controlled.

In the aforementioned method of manufacturing a semiconductor laser apparatus according to the second aspect, the melting point of the second bonding layer is preferably lower than the melting point of the first bonding layer, and the step of bonding the second semiconductor laser device preferably has heat treatment performed at a temperature lower than the melting point of the first bonding layer and higher than the melting point of the second bonding layer. According to this structure, when bonding the second semiconductor laser device, the first bonding layer can be inhibited from being remelted so that the first bonded first semiconductor laser device can be inhibited from displacement. Consequently, the semiconductor laser apparatus with high reliability and excellent yield can be further easily manufactured.

The aforementioned method of manufacturing a semiconductor laser apparatus according to the second aspect preferably further comprises a step of forming the first bonding layer on the main surface before the step of bonding the first semiconductor laser device, wherein the step of bonding the first semiconductor laser device includes a step of bonding the first surface to the first bonding layer. According to this structure, the first semiconductor laser device and the second semiconductor laser device are bonded such that sides provided with a first semiconductor device layer and a second semiconductor device layer with respect to a first semiconductor substrate and a second semiconductor substrate respectively are close to the support member. In other words, the first semiconductor laser device and the second semiconductor laser device are mounted in a junction-down manner with respect to the support member, and hence heat can be efficiently radiated from the first semiconductor device layer and the second semiconductor device layer which are heat generation sources toward the support member. Consequently, temperature characteristics and reliability of the first semiconductor laser device and the second semiconductor laser device can be improved.

The aforementioned method of manufacturing a semiconductor laser apparatus according to the second aspect preferably further comprises a step of forming the second bonding layer on the third surface before the step of bonding the second semiconductor laser device, wherein the step of bonding the second semiconductor laser device includes a step of bonding the second bonding layer to the main surface. According to this structure, the second bonding layer may not be formed on the main surface of the support member, and hence short circuit caused by contact of the second bonding layer with the first bonding layer due to fusion of the second bonding layer can be inhibited from occurrence when heat treatment in bonding the first semiconductor laser device is performed. Further, the third surface can be inhibited from oxidation before bonding the second semiconductor laser device, and hence poor bonding of the second semiconductor laser device can be inhibited.

The aforementioned method of manufacturing a semiconductor laser apparatus according to the second aspect preferably further comprises a step of placing a pellet made of a bonding material on the main surface before the step of bonding the second semiconductor laser device, wherein the step of bonding the second semiconductor laser device includes a step of pressing the second semiconductor laser device to the pellet. According to this structure, the second bonding layer may not be formed on the second semiconductor laser device before the second semiconductor laser device is bonded. Thus, a manufacturing process can be simplified.

An optical apparatus according to a third aspect of the present invention comprises a semiconductor laser apparatus and an optical system adjusting a laser beam emitted from the semiconductor laser apparatus, wherein the semiconductor laser apparatus includes a support member having a main surface, a first semiconductor laser device bonded onto the main surface through a first bonding layer and a second semiconductor laser device bonded onto the main surface through a second bonding layer, wherein the first semiconductor laser device has a first surface and a second surface opposite to the first surface, the second semiconductor laser device has a third surface and a fourth surface opposite to the third surface, the second semiconductor laser device is arranged to be adjacent to the first semiconductor laser device, the first surface of the first semiconductor laser device is bonded onto the main surface, the third surface of the second semiconductor laser device is bonded onto the main surface, the melting point of the second bonding layer is lower than that of the first bonding layer, and a first height from the main surface to the fourth surface is larger than a second height from the main surface to the second surface. The “optical apparatus” in the present invention indicates a wide concept including an optical pickup and an optical disc apparatus performing recording in an optical disc such as a CD, a DVD or a BD, or reproduction and a display device such as a projector or a display.

In the optical apparatus according to the third aspect of the present invention, as hereinabove described, a height of the second semiconductor laser device from the main surface of the support member (first height from the main surface to the fourth surface) is larger than a height of the first semiconductor laser device from the main surface of the support member (second height from the main surface to the second surface), and hence the second semiconductor laser device can be easily bonded also after bonding the first semiconductor laser device. When each semiconductor laser device is bonded using a fixture, for example, a fixture used when bonding the second semiconductor laser device can be inhibited from being in contact with the first bonded first semiconductor laser device. Thus, the first semiconductor laser device can be inhibited from being damaged and the second semiconductor laser device can be excellently bonded onto the support member, and hence poor bonding of the second semiconductor laser device is unlikely to occur.

The melting point of the second bonding layer employed for bonding the second semiconductor laser device is lower than that of the first bonding layer employed for bonding the first semiconductor laser device, and hence heat treatment in bonding the second semiconductor laser device can be performed at a lower temperature than the melting point of the first bonding layer. Thus, also in a case where the first semiconductor laser device is first bonded, for example, the first bonding layer can be inhibited from being remelted when bonding the second semiconductor laser device, whereby the first bonded first semiconductor laser device can be inhibited from displacement.

Consequently, reliability of the aforementioned semiconductor laser apparatus can be improved, and the aforementioned semiconductor laser apparatus with excellent yield can be obtained. Further, The first and second semiconductor laser devices can be arranged to be adjacent to each other, and hence regions from which laser beams are emitted (light-emitting points) thereof can be brought close to each other. Thus, optical components or the like can be easily downsized, alignment can be easily performed and so on when forming the optical apparatus, and hence the optical apparatus can be also easily downsized and the weight thereof can be also easily reduced. Consequently, reliability of the optical apparatus according to the third aspect can be improved, the optical apparatus can be downsized and the weight thereof can be reduced.

According to the present invention, the semiconductor laser apparatus with high reliability and excellent yield and the method of the same can be provided, and the optical apparatus with high reliability, capable of reducing in size and weight can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a semiconductor laser apparatus according to a first embodiment of the present invention cut perpendicularly to a laser beam emitting direction;

FIG. 2 is a sectional view of a blue-violet semiconductor laser device of FIG. 1 cut perpendicularly to the laser beam emitting direction;

FIG. 3 is a sectional view of a red semiconductor laser device of FIG. 1 cut perpendicularly to the laser beam emitting direction;

FIG. 4 is a sectional view for illustrating a manufacturing process of the semiconductor laser apparatus according to the first embodiment of the present invention;

FIG. 5 is a sectional view for illustrating the manufacturing process of the semiconductor laser apparatus according to the first embodiment of the present invention;

FIG. 6 is a sectional view for illustrating the manufacturing process of the semiconductor laser apparatus according to the first embodiment of the present invention;

FIG. 7 is a sectional view of a semiconductor laser apparatus according to a second embodiment of the present invention cut perpendicularly to a laser beam emitting direction;

FIG. 8 is a sectional view of a red/infrared two-wavelength semiconductor laser device of FIG. 7 cut perpendicularly to the laser beam emitting direction;

FIG. 9 is a sectional view for illustrating a manufacturing process of the semiconductor laser apparatus according to the second embodiment of the present invention;

FIG. 10 is a sectional view for illustrating the manufacturing process of the semiconductor laser apparatus according to the second embodiment of the present invention;

FIG. 11 is a sectional view of a semiconductor laser apparatus according to a modification of the second embodiment of the present invention cut perpendicularly to a laser beam emitting direction;

FIG. 12 is a block diagram of an optical pickup according to a third embodiment of the present invention;

FIG. 13 is an external perspective view of a semiconductor laser apparatus of FIG. 12;

FIG. 14 is a front elevational view of a semiconductor laser apparatus of FIG. 13 in a state where a lid is removed as viewed from a laser beam emitting direction; and

FIG. 15 is a block diagram of an optical disc apparatus according to a fourth embodiment of the present invention.

### DESCRIPTION OF THE PREFERRED EMBODIMENTS

Embodiments of the present invention are now described with reference to the drawings.

### First Embodiment

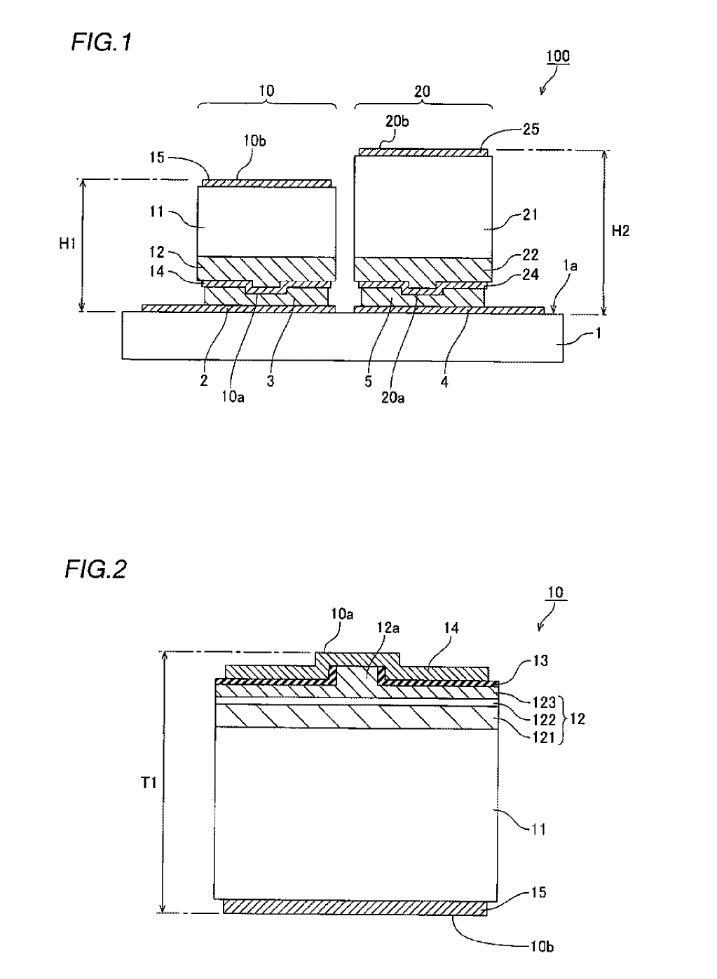

A structure of a semiconductor laser apparatus 100 according to a first embodiment of the present invention is now described with reference to FIGS. 1 to 3.

In the semiconductor laser apparatus 100, a blue-violet semiconductor laser device 10 and a red semiconductor laser device 20 are bonded onto an upper surface 1a of a submount 1 made of AlN to be adjacent to each other and are arranged such that laser beams thereof are emitted parallel to each other. The submount 1 and the upper surface 1a of the submount 1 are examples of the “support member” and the “main surface of the support member” in the present invention, respectively, and the blue-violet semiconductor laser device 10 and the red semiconductor laser device 20 are examples of the “first semiconductor laser device” and the “second semiconductor laser device” in the present invention, respectively. The submount 1 is also an example of the “heat radiation substrate” in the present invention.

The blue-violet semiconductor laser device 10 is bonded onto a connecting electrode 2 having a thickness of about 1 μm formed on the upper surface 1a of the submount 1 through a bonding layer 3 having a thickness of about 3 μm in a junction-down manner. The bonding layer 3 is made of Au (80%)-Sn (20%) solder having a melting point of about 280° C. The red semiconductor laser device 20 is bonded onto a connecting electrode 4 having a thickness of about 1 μm formed on the upper surface 1a of the submount 1 through a bonding layer 5 having a thickness of about 3 μm identical to the thickness of the bonding layer 3 in a junction-down manner. The bonding layer 5 is made of Au (10%)-Sn (90%) solder having a melting point of about 210° C. The bonding layers 3 and 5 are examples of the “first bonding layer” and the “second bonding layer” in the present invention, respectively.

As shown in FIG. 2, in the blue-violet semiconductor laser device 10, a GaN-based semiconductor device layer 12 in which an n-type AlGaN cladding layer 121, an MQW active layer 122 made of InGaN/GaN and a p-type AlGaN cladding layer 123 are stacked in this order is formed on an n-type GaN substrate 11. The n-type GaN substrate 11 and the GaN-based semiconductor device layer 12 are examples of the “first semiconductor substrate” and the “first semiconductor device layer” in the present invention, respectively. A ridge portion 12a is formed on an upper surface of the GaN-based semiconductor device layer 12, and the upper surface of the GaN-based semiconductor device layer 12 excluding an upper surface of the ridge portion 12a is covered with a current blocking layer 13. A p-side electrode 14 is formed on the current blocking layer 13 and is electrically connected to the GaN-based semiconductor device layer 12 on the upper surface of the ridge portion 12a exposed from the current blocking layer 13. The p-side electrode 14 is constituted by an ohmic electrode in which a Pt layer, a Ed layer and a Pt layer are formed in this order from the cladding layer 123 and a pad electrode in which a Ti layer (thickness: 20 nm), an Au layer (thickness: 100 nm), a Ti layer (thickness: 50 nm) and an Au layer (thickness: 3 μm) are formed in this order on the ohmic electrode. The Au layer having a thickness of 3 μm located on an outermost surface of the p-side electrode 14 is alloyed with and integrated with the bonding layer 3 after being bonded to the bonding layer 3, as described later. The p-side electrode 14 is an example of the “first electrode” in the present invention. An n-side electrode 15 is formed on a lower surface of the n-type GaN substrate 11. A thickness of the blue-violet semiconductor laser device 10 (thickness from an upper surface 10a of the blue-violet semiconductor laser device 10 (upper surface of the p-side electrode 14) to a lower surface 10b of the blue-violet semiconductor laser device 10 (lower surface of the n-side electrode 15): T1) is about 90 μm. The upper surface 10a and the lower surface 10b are examples of the “first surface” and the “second surface” in the present invention, respectively. In the blue-violet semiconductor laser device 10, a blue-violet laser beam having a wavelength of about 405 nm is emitted from a region (light-emitting point) located under the ridge portion 12a, of the MQW active layer 122.

As shown in FIG. 1, the blue-violet semiconductor laser device 10 is bonded onto the submount 1 in the junction-down manner, and a side in which the GaN-based semiconductor device layer 12 is formed, of the blue-violet semiconductor laser device 10 (p-side electrode 14) is bonded to the bonding layer 3. A height of the blue-violet semiconductor laser device 10 from the upper surface 1a of the submount 1 (height from the upper surface 1a of the submount 1 to the lower surface 10b of the blue-violet semiconductor laser device 10 (lower surface of the n-side electrode 15): H1) is about 94 μm. The aforementioned height (H1) of the blue-violet semiconductor laser device 10 from the upper surface 1a of the submount 1 is an example of the “second height” in the present invention.

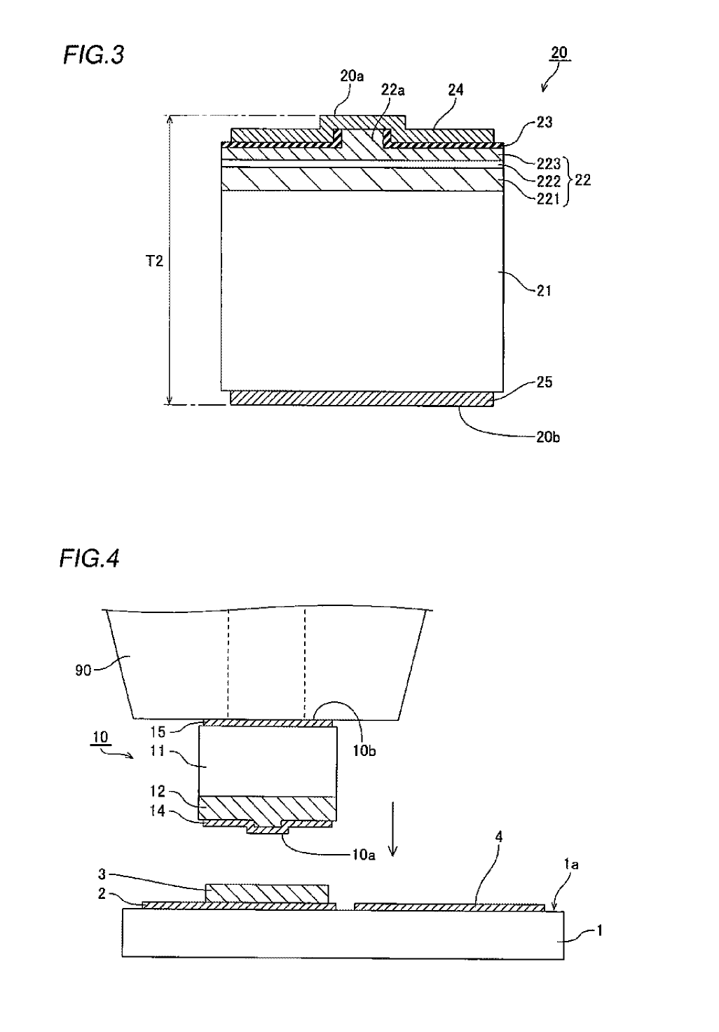

As shown in FIG. 3, in the red semiconductor laser device 20, a GaInP-based semiconductor device layer 22 in which an n-type AlGaInP cladding layer 221, an MQW active layer 222 made of GaInP/AlGaInP and a p-type AlGaInP cladding layer 223 are stacked in this order is formed on an upper surface of an n-type GaAs substrate 21. The n-type GaAs substrate 21 and the GaInP-based semiconductor device layer 22 are examples of the “second semiconductor substrate” and the “second semiconductor device layer” in the present invention, respectively. A ridge portion 22a is formed on an upper surface of the GaInP-based semiconductor device layer 22, and the upper surface of the GaInP-based semiconductor device layer 22 excluding an upper surface of the ridge portion 22a is covered with a current blocking layer 23. A p-side electrode 24 is formed on the current blocking layer 23 and is electrically connected to the GaInP-based semiconductor device layer 22 on the upper surface of the ridge portion 22a exposed from the current blocking layer 23. The p-side electrode 24 is an example of the “second electrode” in the present invention. An n-side electrode 25 is formed on a lower surface of the n-type GaAs substrate 21. A thickness of the red semiconductor laser device 20 (thickness from an upper surface 20a of the red semiconductor laser device 20 (upper surface of the p-side electrode 24) to a lower surface 20b of the red semiconductor laser device 20 (lower surface of the n-side electrode 25): T2) is about 110 μm. The upper surface 20a and the lower surface 20b are examples of the “third surface” and the “fourth surface” in the present invention, respectively. In the red semiconductor laser device 20, a red laser beam having a wavelength of about 650 nm is emitted from a region (light-emitting point) located under the ridge portion 22a, of the MQW active layer 222.

As shown in FIG. 1, the red semiconductor laser device 20 is bonded onto the submount 1 in the junction-down manner, and a side formed with the GaInP-based semiconductor device layer 22, of the red semiconductor laser device 20 (p-side electrode 24) is bonded to the bonding layer 5. A height of the red semiconductor laser device 20 from the upper surface 1a of the submount 1 (height from the upper surface 1a of the submount 1 to a lower surface 20b of the red semiconductor laser device 20 (lower surface of the n-side electrode 25): H2) is about 114 μm. The aforementioned height (H2) of the red semiconductor laser device 20 from the upper surface 1a of the submount 1 is an example of the “first height” in the present invention. Thus, the semiconductor laser apparatus 100 is formed.

In this semiconductor laser apparatus 100, as hereinabove described, the height (H2) of the red semiconductor laser device 20 from the upper surface 1a of the submount 1 is larger than the height (H1) of the blue-violet semiconductor laser device 10 from the upper surface 1a, and hence the red semiconductor laser device 20 can be easily bonded also after the blue-violet semiconductor laser device 10 is bonded. When each semiconductor laser device is bonded using a collet, for example, the blue-violet semiconductor laser device 10 is bonded using a collet and thereafter the red semiconductor laser device 20 is bonded, whereby a collet used when bonding the red semiconductor laser device 20 can be inhibited from being in contact with the first bonded blue-violet semiconductor laser device 10. Thus, the blue-violet semiconductor laser device 10 can be inhibited from being damaged and the red semiconductor laser device 20 can be excellently bonded onto the submount 1, and hence poor bonding of the red semiconductor laser device 20 is unlikely to occur.

The melting point of the bonding layer 5 is lower than the melting point of the bonding point 3, and hence heat treatment in bonding the red semiconductor laser device 20 can be performed at a lower temperature than the melting point of the bonding layer 3. Thus, also in a case where the blue-violet semiconductor laser device 10 is first bonded, for example, the bonding layer 3 can be inhibited from being remelted when bonding the red semiconductor laser device 20, whereby the first bonded blue-violet semiconductor laser device 10 can be inhibited from displacement. Consequently, the semiconductor laser apparatus 100 with high reliability and excellent yield can be obtained in the aforementioned first embodiment.

Further, the blue-violet semiconductor laser device 10 and the red semiconductor laser device 20 can be arranged to be adjacent to each other, and hence the regions from which the laser beams are emitted (light-emitting points) thereof can be brought close to each other. Thus, optical components can be easily downsized, alignment can be easily performed and so on when mounting the semiconductor laser apparatus 100 on an optical apparatus such as an optical pickup, or the like.

The heights of the blue-violet semiconductor laser device 10 and the red semiconductor laser device 20 are different from each other, and hence the blue-violet semiconductor laser device 10 and the red semiconductor laser device 20 can be easily identified, and the front and the back of the semiconductor laser apparatus 100 can be easily identified, for example. Thus, the semiconductor laser apparatus 100 can be easily mounted on the optical pickup, the optical apparatus or the like, and an arrangement of a peripheral optical system or the like can be easily performed without a mistake. The melting points of the bonding layers 3 and 5 are different from each other, and hence only the bonding layer 5 can be remelted to adjust a position of the red semiconductor laser device 20, for example. Thus, the bonding layer 3 can be inhibited from being remelted without excessively increasing a heat treatment temperature, and positions of the light-emitting points of the blue-violet semiconductor laser device 10 and the red semiconductor laser device 20 can be precisely controlled in the aforementioned case.

In this semiconductor laser apparatus 100, as hereinabove described, the blue-violet semiconductor laser device 10 and the red semiconductor laser device 20 are bonded such that sides provided with the GaN-based semiconductor device layer 12 and the GaInP-based semiconductor device layer 22 with respect to the n-type GaN substrate 11 and the n-type GaAs substrate 21 respectively are close to the submount 1. In other words, the blue-violet semiconductor laser device 10 and the red semiconductor laser device 20 are mounted in the junction-down manner with respect to the submount 1, and hence heat can be efficiently radiated from the GaN-based semiconductor device layer 12 and the GaInP-based semiconductor device layer 22 which are heat generation sources toward the submount 1. Consequently, temperature characteristics and reliability of the blue-violet semiconductor laser device 10 and the red semiconductor laser device 20 can be improved.

Thicknesses of the GaN-based semiconductor device layer 12 and the GaInP-based semiconductor device layer 22 are controlled, whereby heights of the light-emitting points of the blue-violet semiconductor laser device 10 and the red semiconductor laser device 20 from the upper surface 1a of the submount 1 can be easily equalized with each other. Thus, a position of each of the light-emitting points can be precisely controlled when this semiconductor laser apparatus 100 is employed as a light source of the optical apparatus such as the optical pickup.

In this semiconductor laser apparatus 100, as hereinabove described, the thickness (T2) of the red semiconductor laser device 20 is larger than the thickness (T1) of the blue-violet semiconductor laser device 10. Thus, the height (H2) of the red semiconductor laser device 20 can be easily rendered larger than the height (H1) of the blue-violet semiconductor laser device 10. The thicknesses of the connecting electrodes 2 and 4 are equalized with each other and the thicknesses of the bonding layers 3 and 5 are also equalized with each other, and hence the height (H1) of the blue-violet semiconductor laser device 10 and the height (H2) of the red semiconductor laser device 20 can be easily controlled by the thickness (T1) of the blue-violet semiconductor laser device 10 and the thickness (T2) of the red semiconductor laser device 20, respectively.

As hereinabove described, this semiconductor laser apparatus 100 comprises the blue-violet semiconductor laser device 10 and the red semiconductor laser device 20 as the first semiconductor laser device and the second semiconductor laser device in the present invention, and hence the laser beams having different wavelengths from each other can be emitted. Thus, the semiconductor laser apparatus 100 can be employed in a compatible optical pickup adapted to operate for a plurality of types of optical discs such as a CD, a DVD and a BD. This semiconductor laser apparatus 100 can be employed in a compatible optical pickup for a DVD and a BD.

In this semiconductor laser apparatus 100, as hereinabove described, the height (H1) of the blue-violet semiconductor laser device 10 in which the wavelength of the laser beam is short is smaller than the height (H2) of the red semiconductor laser device 20 in which the wavelength of the laser beam is long. In other words, the blue-violet semiconductor laser device 10 in which the GaN substrate 11 with poor workability is employed is thinner than the red semiconductor laser device 20 in which the GaAs substrate 21 is employed, and hence the blue-violet semiconductor laser device 10 can be easily separated into chips.

A manufacturing process of the semiconductor laser apparatus 100 is now described with reference to FIGS. 1 to 6.

As shown in FIG. 4, the connecting electrodes 2 and 4 are formed on the upper surface 1a of the submount 1 at a prescribed distance from each other, and thereafter the bonding layer 3 is formed on the connecting electrode 2. Then, the lower surface 10b of the blue-violet semiconductor laser device 10 (surface on a side in which the n-side electrode 15 is formed with respect to the n-type GaN substrate 11) is adsorbed using a collet 90, and the blue-violet semiconductor laser device 10 is held while directing the upper surface 10a (surface on a side in which the GaN-based semiconductor device layer 12 and the p-side electrode 14 are formed with respect to the n-type GaN substrate 11) to the bonding layer 3, as shown in FIG. 4. The submount 1 is heated to a temperature higher than the melting point of the bonding layer 3 while the p-side electrode 14 is pressed to the bonding layer 3, thereby melting the bonding layer 3. Thereafter, the submount 1 is cooled down and the bonding layer 3 is solidified, whereby the blue-violet semiconductor laser device 10 is bonded onto the submount 1 in the junction-down manner. At this time, the Au layer having a thickness of 3 μm located on the outermost surface of the p-side electrode 14 is alloyed with and completely integrated with the bonding layer 3 made of Au (80%)-Sn (20%) solder.

As shown in FIGS. 3 and 5, the bonding layer 5 is formed on the upper surface 20a of the red semiconductor laser device 20 (surface on a side in which the GaInP-based semiconductor device layer 22 and the p-side electrode 24 are formed with respect to the n-type GaAs substrate 21), and thereafter the lower surface 20b of the red semiconductor laser device 20 (surface on a side in which the n-side electrode 25 is formed with respect to the n-type GaAs substrate 21) is adsorbed using the collet 90, and the red semiconductor laser device 20 is held while directing the upper surface to the connecting electrode 4.

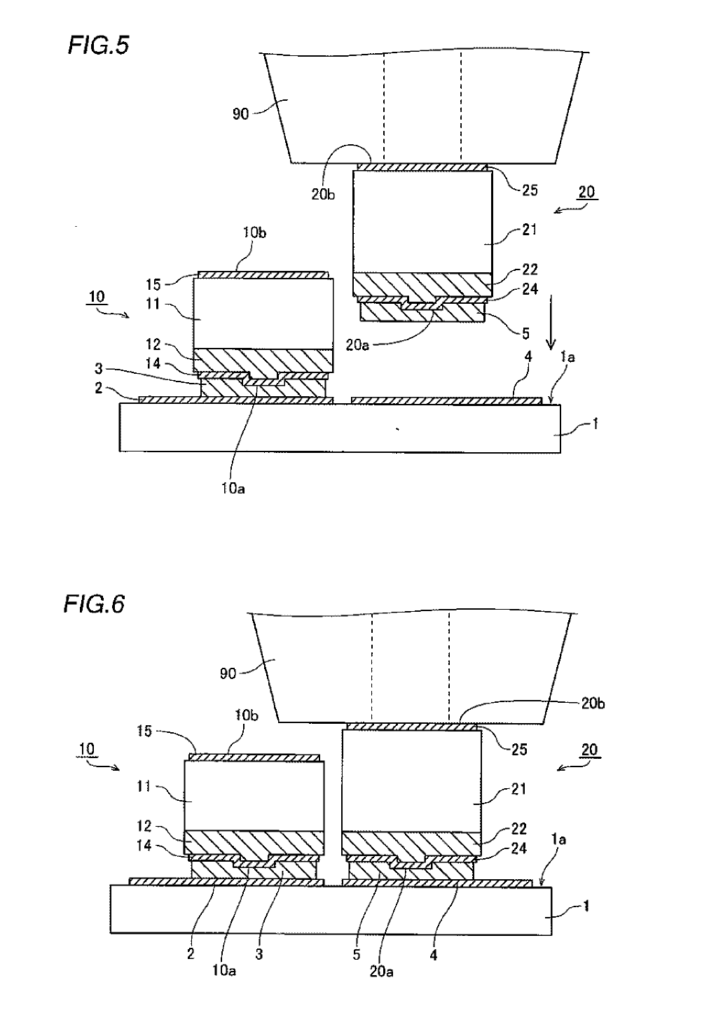

As shown in FIG. 6, the submount 1 is heated to a temperature lower than the melting point of the bonding layer 3 and higher than the melting point of the bonding layer 5 while the bonding layer 5 is pressed to the connecting electrode 4, thereby melting the bonding layer 5. Thereafter, the submount 1 is cooled down and the bonding layer 5 is solidified, whereby the red semiconductor laser device 20 is bonded onto the submount 1 in the junction-down manner. Thus, the semiconductor laser apparatus 100 is manufactured.

In a method of manufacturing this semiconductor laser apparatus 100, as hereinabove described, the melting point of the bonding layer 5 employed for bonding the red semiconductor laser device 20 is lower than the melting point of the bonding layer 3 employed for bonding the blue-violet semiconductor laser device 10, and the heat treatment in bonding the red semiconductor laser device 20 is performed at a lower temperature than the melting point of the bonding layer 3. Thus, when bonding the red semiconductor laser device 20, the bonding layer 3 can be inhibited from being remelted so that the first bonded blue-violet semiconductor laser device 10 can be inhibited from displacement. Consequently, the semiconductor laser apparatus 100 with high reliability and excellent yield can be further easily manufactured.

As hereinabove described, the method of manufacturing this semiconductor laser apparatus 100 further comprises a step of forming the bonding layer 5 on the upper surface 20a of the red semiconductor laser device 20 before a step of bonding the red semiconductor laser device 20, and a step of bonding the red semiconductor laser device 20 onto the submount 1 includes a step of bonding the bonding layer 5 onto the submount 1. Thus, the bonding layer 5 may not be formed on the upper surface 1a of the submount 1, and hence short circuit caused by contact of the bonding layer 5 with the bonding layer 3 due to fusion of the bonding layer 5 can be inhibited from occurrence when heat treatment in bonding the blue-violet semiconductor laser device 10 is performed. Further, the upper surface 20a can be inhibited from oxidation before bonding the red semiconductor laser device 20, and hence poor bonding of the red semiconductor laser device 20 can be inhibited.

In the method of manufacturing this semiconductor laser apparatus 100, as hereinabove described, the blue-violet semiconductor laser device 10 is first bonded, and the red semiconductor laser device 20 is then bonded. Thus, the temperature of the heat treatment given to the red semiconductor laser device 20 made of GaInP-based semiconductor with relatively lower thermal stability than GaN-based semiconductor can be reduced, and hence thermal damage given to the red semiconductor laser device 20 can be inhibited. Consequently, reliability of this semiconductor laser apparatus 100 can be improved.

In the method of manufacturing this semiconductor laser apparatus 100, as hereinabove described, the Au layer having a thickness of 3 μm is formed so as to be located on the outermost of the p-side electrode 14. Thus, the Au layer is alloyed with and completely integrated with the bonding layer 3 made of Au (80%)-Sn (20%) solder, and hence the blue-violet semiconductor laser device 10 can be strongly bonded to the submount 1 through the bonding layer 3.

### Second Embodiment

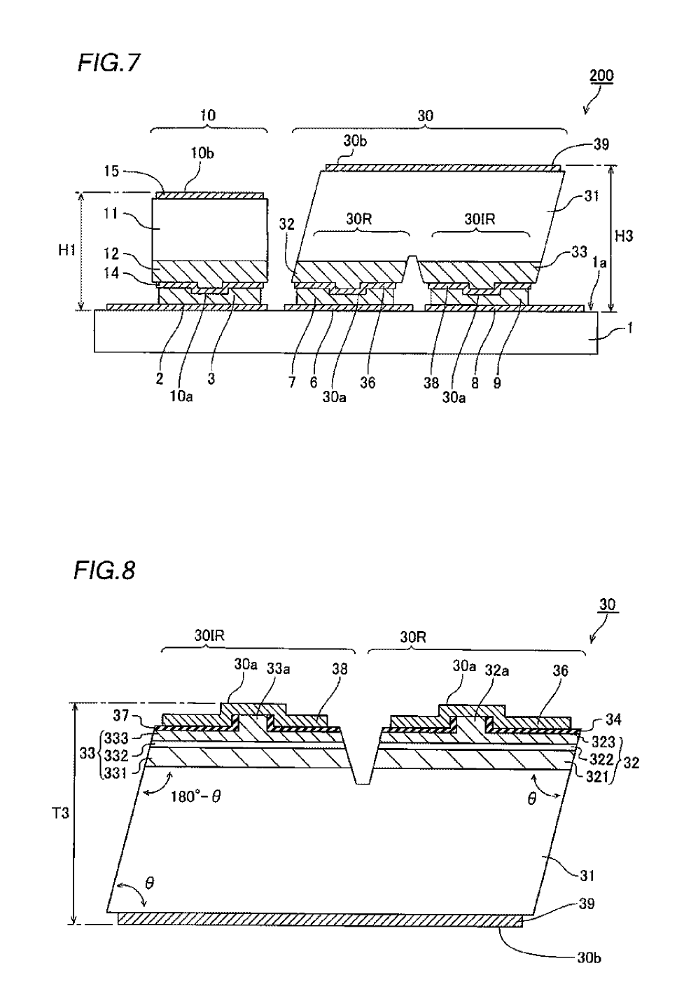

A case of forming a three-wavelength semiconductor laser apparatus by employing a red/infrared two-wavelength semiconductor laser device in place of the red semiconductor laser device in the aforementioned first embodiment is now described with reference to FIGS. 7 and 8. A structure similar to that in the aforementioned first embodiment is denoted by the same reference numerals and redundant description is omitted.

In a semiconductor laser apparatus 200 according to the second embodiment of the present invention, a blue-violet semiconductor laser device 10 and the red/infrared two-wavelength semiconductor laser device 30 are bonded to be adjacent to each other and are arranged such that laser beams thereof are emitted parallel to each other, as shown in FIG. 7. The red/infrared two-wavelength semiconductor laser device 30 is an example of the “second semiconductor laser device” in the present invention. The red/infrared two-wavelength semiconductor laser device 30 is bonded onto connecting electrodes 6 and 8 having thicknesses of about 1 μm formed on an upper surface 1a of a submount 1 through bonding layers 7 and 9 having thicknesses of about 3 μm in a junction-down manner. The bonding layers 7 and 9 are each made of Au (10%)-Sn (90%) solder having a melting point of about 210° C. and are examples of the “second bonding layer” in the present invention.

As shown in FIG. 8, the red/infrared two-wavelength semiconductor laser device 30 has a substantially parallelogram cross-sectional shape and comprises a red semiconductor laser device structure 30R and an infrared semiconductor laser device structure 30IR on an upper surface of an n-type GaAs substrate 31.

A GaInP-based semiconductor device layer 32 in which an n-type AlGaInP cladding layer 321, an MQW active layer 322 made of GaInP/AlGaInP and a p-type AlGaInP cladding layer 323 are stacked in this order is formed on a prescribed region of the upper surface of the n-type GaAs substrate 31 (region along a side surface on a side in which an angle (θ) formed by the upper surface and the side surface of the n-type GaAs substrate 31 is an acute angle). The n-type GaAs substrate 31 and the GaInP-based semiconductor device layer 32 are examples of the “second semiconductor substrate” and the “second semiconductor device layer” in the present invention, respectively. A ridge portion 32a is formed on an upper surface of the GaInP-based semiconductor device layer 32, and the upper surface of the GaInP-based semiconductor device layer 32 excluding an upper surface of the ridge portion 32a is covered with a current blocking layer 34. A p-side electrode 36 is formed on the current blocking layer 34 and is electrically connected to the GaInP-based semiconductor device layer 32 on the upper surface of the ridge portion 32a exposed from the current blocking layer 34. The p-side electrode 36 is an example of the “second electrode” in the present invention. Thus, the red semiconductor laser device structure 30R is formed in a region where the GaInP-based semiconductor device layer 32 is formed. In the red semiconductor laser device structure 30R, a red laser beam having a wavelength of about 650 nm is emitted from a region (light-emitting point) located under the ridge portion 32a, of the MQW active layer 322.

A GaAs-based semiconductor device layer 33 in which an n-type AlGaAs cladding layer 331, an MQW active layer 332 made of AlGaAs and a p-type AlGaAs cladding layer 333 are stacked in this order is formed on a region where the GaInP-based semiconductor device layer 32 is not formed, of the upper surface of the n-type GaAs substrate 31 (region along a side surface on a side in which an angle (180°−θ) formed by the upper surface and the side surface of the n-type GaAs substrate 31 is an obtuse angle). The GaAs-based semiconductor device layer 33 is an example of the “second semiconductor device layer” in the present invention. A ridge portion 33a is formed on an upper surface of the GaAs-based semiconductor device layer 33, and the upper surface of the GaAs-based semiconductor device layer 33 excluding an upper surface of the ridge portion 33a is covered with a current blocking layer 37. A p-side electrode 38 is formed on the current blocking layer 37 and is electrically connected to the GaAs-based semiconductor device layer 33 on the upper surface of the ridge portion 33a exposed from the current blocking layer 38. The p-side electrode 38 is an example of the “second electrode” in the present invention. Thus, the infrared semiconductor laser device structure 3018 is formed on a region where the GaAs-based semiconductor device layer 33 is formed. In the infrared semiconductor laser device structure 30IR, an infrared laser beam having a wavelength of about 780 nm is emitted from a region (light-emitting point) located under the ridge portion 33a, of the MQW active layer 332.

An n-side electrode 39 is formed on a lower surface of the n-type GaAs substrate 31. Regarding a thickness of the red/infrared two-wavelength semiconductor laser device 30 (thickness from an upper surface 30a of the red/infrared two-wavelength semiconductor laser device 30 (upper surfaces of the p-side electrodes 36 and 38) to a lower surface 30b of the red/infrared two-wavelength semiconductor laser device 30 (lower surface of the n-side electrode 39): T3), thicknesses from the upper surfaces of the p-side electrodes 36 and 38 to the lower surface of the n-side electrode 39 are equal to each other and are about 110 μm. The upper surface 30a and the lower surface 30b are examples of the “third surface” and the “fourth surface” in the present invention, respectively.

As shown in FIG. 7, the red/infrared two-wavelength semiconductor laser device 30 is bonded onto the submount 1 in the junction-down manner such that the red semiconductor laser device structure 30R is adjacent to the blue-violet semiconductor laser device 10. In other words, the p-side electrode 36 of the red semiconductor laser device structure 30R and the bonding layer 7 on the connecting electrode 6 are bonded to each other, and the p-side electrode 38 of the infrared semiconductor laser device structure 30IR and the bonding layer 9 on the connecting electrode 8 are bonded to each other. A height of the red/infrared two-wavelength semiconductor laser device 30 from the upper surface 1a of the submount 1 (height from the upper surface 1a of the submount 1 to the lower surface 30b of the red/infrared two-wavelength semiconductor laser device 30 (lower surface of the n-side electrode 39): H3) is about 114 μm. The aforementioned height (H3) of the red/infrared two-wavelength semiconductor laser device 30 from the upper surface 1a of the submount 1 is an example of the “first height” in the present invention. The cross section of the red/infrared two-wavelength semiconductor laser device 30 is substantially parallelogram shaped as hereinabove described, and hence an interval between the blue-violet semiconductor laser device 10 and the red/infrared two-wavelength semiconductor laser device 30 is narrow on a side closer to the upper surface 1a of the submount 1 and becomes wider with increasing distance from the submount 1. The remaining structure of the semiconductor laser apparatus 200 is similar to that of the aforementioned semiconductor laser apparatus 100.

In this semiconductor laser apparatus 200, as hereinabove described, the red/infrared two-wavelength semiconductor laser device 30 is monolithically-integrated, and hence a semiconductor laser apparatus emitting laser beams of three wavelengths can be easily obtained. Thus, this semiconductor laser apparatus 200 can be employed in a compatible optical pickup for a CD, a DVD and a BD.

In this semiconductor laser apparatus 200, as hereinabove described, the thicknesses (T3) of the red semiconductor laser device structure 30R and the infrared semiconductor laser device structure 30IR of the red/infrared two-wavelength semiconductor laser device 30 are equalized with each other, and hence the red/infrared two-wavelength semiconductor laser device 30 can be easily bonded onto the submount 1.

In this semiconductor laser apparatus 200, as hereinabove described, the bonding layers 7 and 9 are made of the same types of solder having the same melting points, and the thicknesses thereof are equalized with each other. Thus, the red/infrared two-wavelength semiconductor laser device 30 can be easily bonded onto the submount 1 through one step.

In this semiconductor laser apparatus 200, as hereinabove described, the cross section of the red/infrared two-wavelength semiconductor laser device 30 is substantially parallelogram shaped, and the interval between the blue-violet semiconductor laser device 10 and the red/infrared two-wavelength semiconductor laser device 30 is narrow on the side closer to the upper surface 1a of the submount 1 and becomes wider with increasing distance from the submount 1. Thus, the light-emitting point of the blue-violet semiconductor laser device 10 and the light-emitting point of the red/infrared two-wavelength semiconductor laser device 30 (light-emitting point of the red semiconductor laser device structure 30R) can be easily brought close to each other.

The remaining effects of this semiconductor laser apparatus 200 are similar to those of the aforementioned semiconductor laser apparatus 100.

A manufacturing process of the semiconductor laser apparatus 200 is now described with reference to FIGS. 7 to 10.

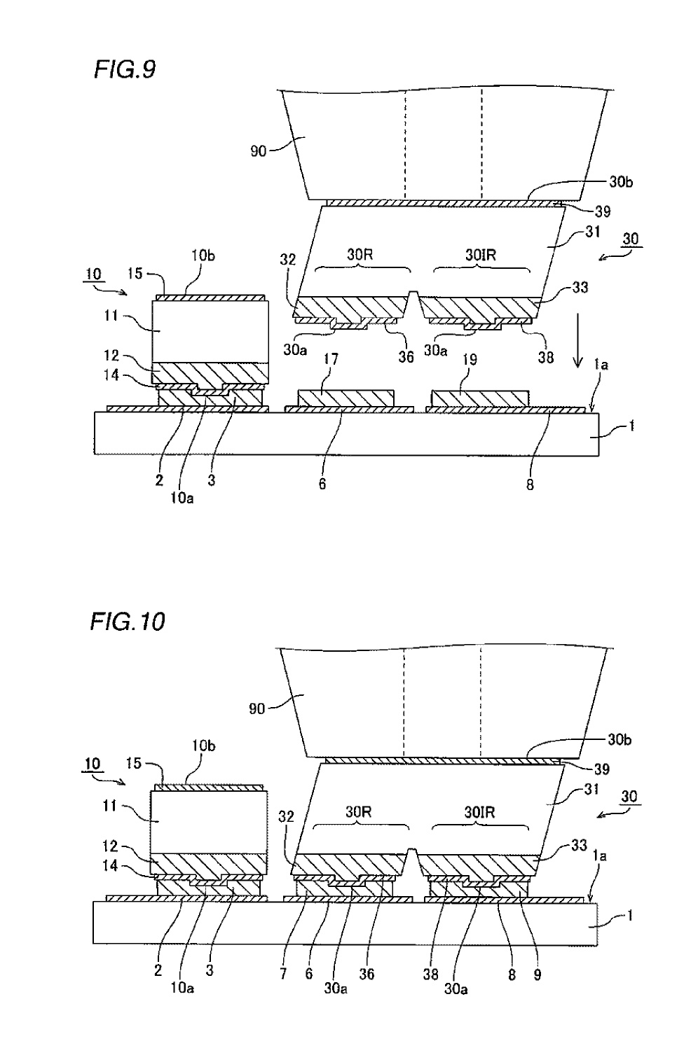

As shown in FIG. 9, a connecting electrode 2 and the connecting electrodes 6 and 8 are formed on the upper surface 1a of the submount 1 at a prescribed distance from each other, and thereafter the blue-violet semiconductor laser device 10 is bonded onto the connecting electrode 2 formed on the submount 1 through a bonding layer 3 in the junction-down manner through a process similar to that of the first embodiment. Then, solder pellets 17 and 19 made of Au (10%)-Sn (90%) solder constituting the bonding layers 7 and 9 are placed on the connecting electrodes 6 and 8. The solder pellets 17 and 19 are examples of the “pellet made of a bonding material” in the present invention. The lower surface 30b of the red/infrared two-wavelength semiconductor laser device 30 (surface on a side in which the n-side electrode 39 is formed with respect to the n-type GaAs substrate 31) is adsorbed, and the red/infrared two-wavelength semiconductor laser device 30 is held while directing the upper surface 30a (surface on a side in which the GaInP-based semiconductor device layer 32, the GaAs-based semiconductor device layer 33, the p-side electrode 36 and the p-side electrode 38 are formed with respect to the n-type GaAs substrate 31) to the submount 1. The red/infrared two-wavelength semiconductor laser device 30 is held such that an interval between a side surface adjacent to the blue-violet semiconductor laser device 10 and the blue-violet semiconductor laser device 10 is narrow on the side closer to the upper surface 1a of the submount 1 and becomes wider with increasing distance from the submount 1 and the red semiconductor laser device structure 30R is adjacent to the blue-violet semiconductor laser device 10.

As shown in FIG. 10, the submount 1 is heated to a temperature lower than the melting point of the bonding layer 3 and higher than the melting points of the bonding layers 7 and 9 while the p-side electrodes 36 and 38 are pressed to the solder pellet 17 on the connecting electrode 6 and the solder pellet 19 on the connecting electrode 8 respectively, and thereafter the submount 1 is cooled down. Thus, the solder pellets 17 and 19 are melted and solidified between the p-side electrode 36 and the connecting electrode 6 and the p-side electrode 38 and the connecting electrode 8, whereby the solder pellets 17 and 19 constitute the bonding layers 7 and 9, respectively. Further, the red/infrared two-wavelength semiconductor laser device 30 is bonded onto the submount 1 in the junction-down manner by the bonding layers 7 and 9. Thus, the semiconductor laser apparatus 200 is manufactured.

In the method of manufacturing this semiconductor laser apparatus 200, as hereinabove described, the solder pellets 17 and 19 are placed on the connecting electrodes 6 and 8, and hence the bonding layers 7 and 9 may not be formed on the p-side electrodes 36 and 38 or the connecting electrodes 6 and 8 before the red/infrared two-wavelength semiconductor laser device 30 is bonded. Thus, the manufacturing process can be simplified.

In the method of manufacturing this semiconductor laser apparatus 200, as hereinabove described, the red/infrared two-wavelength semiconductor laser device 30 is bonded onto the submount 1 in a state of being held such that the interval between the side surface adjacent to the blue-violet semiconductor laser device 10 and the blue-violet semiconductor laser device 10 is narrow on the side closer to the upper surface 1a of the submount 1 and becomes wider with increasing distance from the submount 1. Thus, the light-emitting point of the blue-violet semiconductor laser device 10 and the light-emitting point of the red/infrared two-wavelength semiconductor laser device 30 (light-emitting point of the red semiconductor laser device structure 30R) can be easily brought close to each other.

The remaining effects of the method of manufacturing this semiconductor laser apparatus 200 are similar to those of the aforementioned method of manufacturing the semiconductor laser apparatus 100.

(Modification of Second Embodiment)

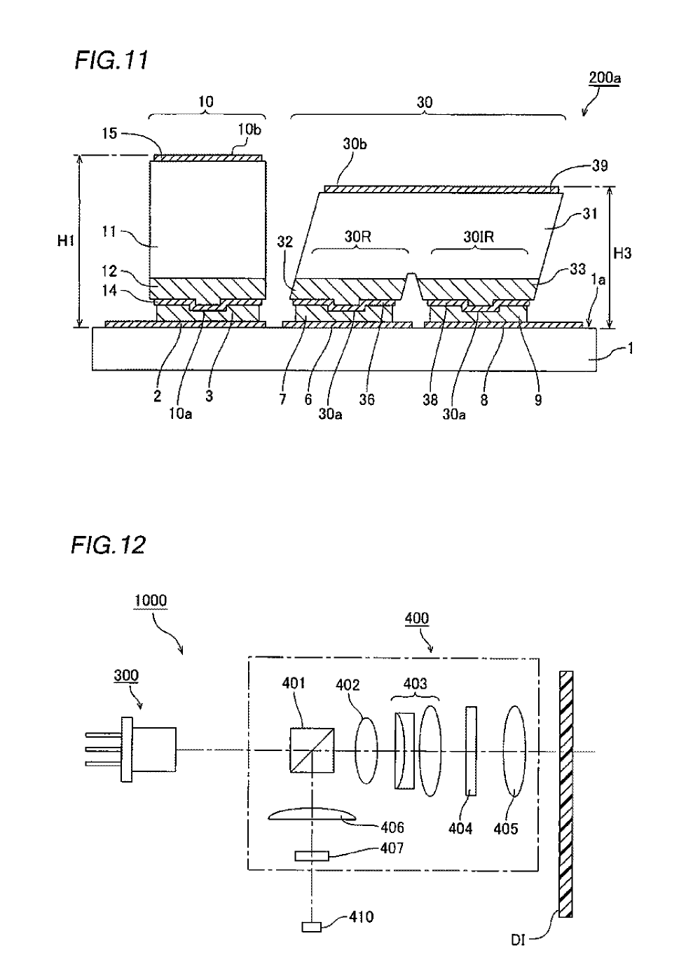

A modification of the second embodiment is now described with reference to FIG. 11. In a semiconductor laser apparatus 200a according to the modification of the second embodiment, a height (H1) of a blue-violet semiconductor laser device 10 is larger than a height (H3) of a red/infrared two-wavelength semiconductor laser device 30 dissimilarly to the aforementioned second embodiment. In this embodiment, the blue-violet semiconductor laser device 10 and the red/infrared two-wavelength semiconductor laser device 30 are examples of the “second semiconductor laser device” and the “first semiconductor laser device” in the present invention, respectively. The height (H1) and the height (H3) are examples of the “first height” and the “second height” in the present invention, respectively. An upper surface 10a and a lower surface 10b of the blue-violet semiconductor laser device 10 are examples of the “third surface” and the “fourth surface” in the present invention, respectively. An upper surface 30a and a lower surface 30b of the red/infrared two-wavelength semiconductor laser device 30 are examples of the “first surface” and the “second surface” in the present invention, respectively. An n-type GaN substrate 11 and an n-type GaAs substrate 31 are examples of the “second semiconductor substrate” and the “first semiconductor substrate” in the present invention, respectively. A GaN-based semiconductor device layer 12 is an example of the “second semiconductor substrate” in the present invention. A GaInP-based semiconductor device layer 32 and a GaAs-based semiconductor device layer 33 are examples of the “first semiconductor device layer” in the present invention.

A bonding layer 3 bonding the blue-violet semiconductor laser device 10 and a connecting electrode 2 is made of Au (10%)-Sn (90%) solder. Bonding layers 7 and 9 bonding the red/infrared two-wavelength semiconductor laser device 30 and the connecting electrodes 6 and 8 are made of Au (80%)-Sn (20%) solder. The bonding layer 3 is an example of the “second bonding layer” in the present invention, and the bonding layers 7 and 9 are examples of the “first bonding layer” in the present invention.

The remaining structure of the semiconductor laser apparatus 200a is similar to that of the semiconductor laser apparatus 200, and a structure similar to that in the aforementioned second embodiment is denoted by the same reference numerals and redundant description is omitted.

In this semiconductor laser apparatus 200a, as hereinabove described, the height (H3) of the red/infrared two-wavelength semiconductor laser device 30 is smaller than the height (H1) of the blue-violet semiconductor laser device 10. Thus, the red/infrared two-wavelength semiconductor laser device 30 can be easily separated into chips. Further, a thickness of the blue-violet semiconductor laser device 10 can be increased, and hence it can be rendered difficult to generate a crack in a wafer process for manufacturing the blue-violet semiconductor laser device 10. The remaining effects of the semiconductor laser apparatus 200a are similar to those of the semiconductor laser apparatus 200.

In a manufacturing process of the semiconductor laser apparatus 200a, an order of bonding the blue-violet semiconductor laser device 10 and the red/infrared two-wavelength semiconductor laser device 30 is rendered reverse to that in the manufacturing process of the semiconductor laser apparatus 200. The bonding layers 7 and 9 are formed through a process similar to that of forming the bonding layer 3 in the first embodiment before bonding the red/infrared two-wavelength semiconductor laser device 30. The bonding layer 3 is formed on the upper surface 10a of the blue-violet semiconductor laser device 10 through a process similar to that of forming the bonding layer 5 in the first embodiment before bonding the blue-violet semiconductor laser device 10. The remaining effects of the method of manufacturing the semiconductor Laser apparatus 200a are similar to those of the method of manufacturing the semiconductor laser apparatus 200.

### Third Embodiment

An optical pickup 1000 according to a third embodiment of the present invention is now described with reference to FIGS. 12 to 14. The optical pickup 1000 is an example of the “optical apparatus” in the present invention.

As shown in FIG. 12, the optical pickup 1000 according to the third embodiment comprises a semiconductor laser apparatus 300 emitting laser beams of three wavelengths of blue-violet, red and infrared, an optical system 400 adjusting the laser beams emitted from the semiconductor laser apparatus 300 and a light detection portion 410 receiving the laser beams.

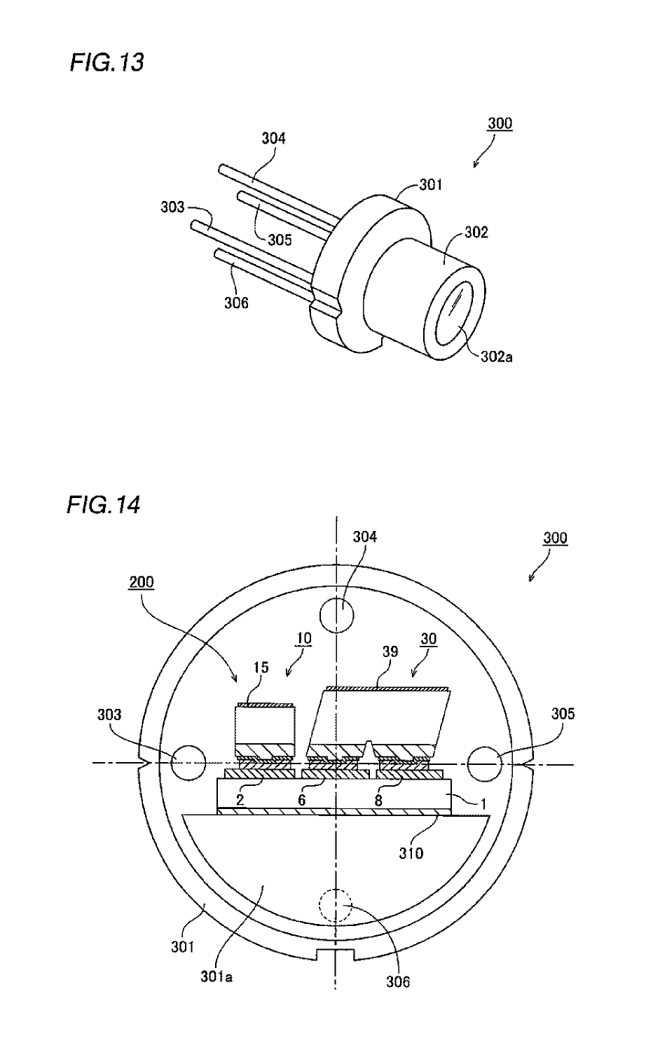

The semiconductor laser apparatus 300 has a base 301 made of a conductive material, a cap 302 arranged on a front surface of the base 301 and leads 303, 304, 305 and 306 mounted on a rear surface of the base 301, as shown in FIGS. 13 and 14. A header 301a is integrally formed with the base 301 on the front surface of the base 301. The aforementioned semiconductor laser apparatus 200 is arranged on an upper surface of the header 301a, and a submount 1 of the semiconductor laser apparatus 200 and the header 301a are fixed by a bonding layer 310 made of solder. An optical window 302a transmitting a laser beam emitted from the semiconductor laser apparatus 200 is mounted on a front surface of the cap 302, and the inside semiconductor laser apparatus 200 is sealed by the cap 302.

The leads 303 to 305 pass through the base 301 and fixed to be electrically insulated from each other through insulating members (not shown). The leads 303 to 305 are electrically connected to connecting electrodes 2, 6 and 8 formed on the submount 1 of the semiconductor laser apparatus 200, respectively through wires (not shown). The lead 306 is integrally formed with the base 301. Each of an n-side electrode 15 of a blue-violet semiconductor laser device 10 and an n-side electrode 39 of a red/infrared two-wavelength semiconductor laser device 30 is electrically connected to the upper surface of the header 301a through a wire (not shown). Thus, the lead 306 is electrically connected to the n-side electrodes 15 and 39, and cathode common connection of the blue-violet semiconductor laser device 10 and the red/infrared two-wavelength semiconductor laser device 30 is achieved.

The optical system 400 has a polarizing beam splitter (hereinafter abbreviated as a polarized BS) 401, a collimator lens 402, a beam expander 403, a λ/4 plate 404, an objective lens 405, a cylindrical lens 406 and an optical axis correction device 407, as shown in FIG. 12.

The polarized BS 401 totally transmits the laser beams emitted from the semiconductor laser apparatus 300 and totally reflects the laser beams returned from an optical disc DI. The collimator lens 402 converts the laser beams transmitting through the polarized BS 401 to parallel lights. The beam expander 403 includes a concave lens, a convex lens and an actuator (not shown). The actuator corrects states of wavefront of the laser beams emitted from the semiconductor laser apparatus 300 by changing a distance of the concave lens and the convex lens in response to a servo signal from a servo circuit described later.

The λ/4 plate 404 converts linearly-polarized laser beams converted to substantially parallel lights by the collimator lens 402 to circularly-polarized lights. The λ/4 plate 404 converts the circularly-polarized laser beams returned from the optical disc DI to linearly-polarized lights. Directions of polarization of linearly-polarized lights in this case are perpendicular to directions of polarization of linear polarization of the laser beams emitted from the semiconductor laser apparatus 300. Thus, the laser beams returned from the optical disc DI is totally reflected by the polarized BS 401. The objective lens 405 converges the laser beams transmitted through the λ/4 plate 404 on a surface (recording layer) of the optical disc DI. The objective lens 405 is movable in a focus direction, a tracking direction and a tilt direction in response to a servo signal (a tracking servo signal, a focus servo signal and a tilt servo signal) from the servo circuit described later by an objective lens actuator (not shown).

The cylindrical lens 406, optical axis correction device 407 and the light detection portion 410 are arranged along an optical axis of the laser beams totally reflected by the polarized BS 401. The cylindrical lens 406 gives astigmatic action to incident laser beams. The optical axis correction device 407 is formed by diffraction grating and so arranged that a spot of zero-order diffracted light of each of blue-violet, red and infrared laser beams transmitted through the cylindrical lens 406 coincides on a detection region of the light detection portion 410 described later.

The light detection portion 410 outputs a signal based on intensity distribution of received laser beams. The light detection portion 410 has a prescribed patterned detection region to obtain a playback signal as well as a focus error signal, a tracking error signal and a tilt error signal. Thus, the optical pickup 1000 is formed.

In this optical pickup 1000, the semiconductor laser apparatus 300 can independently emit blue-violet, red and infrared laser beams from the blue-violet semiconductor laser device 10 and the red/infrared two-wavelength semiconductor laser device 30 by independently applying voltages between the lead 306 and the respective leads 303 to 305. As hereinabove described, the laser beams emitted from the semiconductor laser apparatus 300 are adjusted by the polarized BS 401, the collimator lens 402, the beam expander 403, the λ/4 plate 404, the objective lens 405, the cylindrical lens 406 and the optical axis correction device 407, and thereafter irradiated on the detection region of the light detection portion 410.

When data recorded in the optical disc DI is play backed, the laser beams are applied to the recording layer of the optical disc DI while controlling laser power emitted from the blue-violet semiconductor laser device 10 and the red/infrared two-wavelength semiconductor laser device 30 to be constant and the playback signal output from the light detection portion 410 can be obtained. The actuator of the beam expander 403 and the objective lens actuator driving the objective lens 405 can be feedback-controlled by the focus error signal, the tracking error signal and the tilt error signal simultaneously output.

When data is recorded in the optical disc DI, the laser beams are applied to the optical disc DI while controlling laser power emitted from the blue-violet semiconductor laser device 10 and the red/infrared two-wavelength semiconductor laser device 30 on the basis of data to be recorded. Thus, the data can be recorded in the recording layer of the optical disc DI. Similarly to the above, the actuator of the beam expander 403 and the objective lens actuator driving the objective lens 405 can be feedback-controlled by the focus error signal, the tracking error signal and the tilt error signal output from the light detection portion 410.

Thus, record in the optical disc DI and playback can be performed with the optical pickup 1000.

In the optical pickup 1000, the aforementioned semiconductor laser apparatus 200 is mounted in the semiconductor laser apparatus 300, and hence reliability of the semiconductor laser apparatus 300 can be improved and the blue-violet semiconductor laser device 10 and the red/infrared two-wavelength semiconductor laser device 30 can be arranged to be adjacent to each other. Thus, regions from which the laser beams are emitted (light-emitting points) thereof can be brought close to each other, and hence the optical system 400 and the light detection portion 410 can be easily downsized, alignment can be easily performed and so on. Consequently, according to this embodiment, the optical pickup 1000 with high reliability, capable of reducing in size and weight can be easily obtained. The remaining effects of this optical pickup 1000 are similar to those of the semiconductor laser apparatus 200.

### Fourth Embodiment

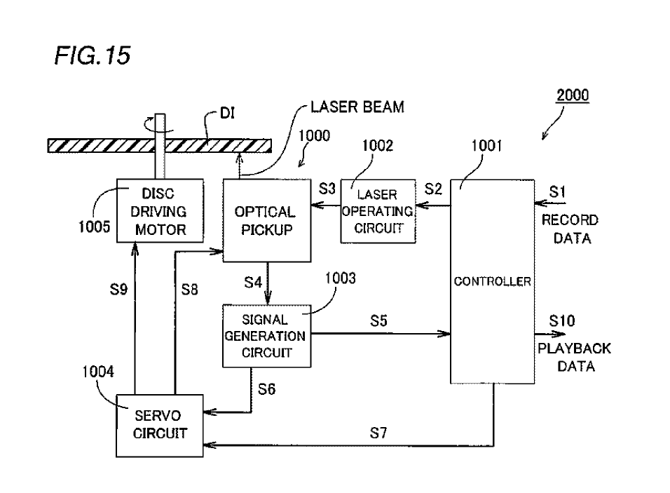

An optical disc apparatus 2000 according to a fourth embodiment of the present invention is now described with reference to FIG. 15. The optical disc apparatus 2000 is an example of the “optical apparatus” in the present invention.

This optical disc apparatus 2000 comprises the aforementioned optical pickup 1000, a controller 1001, a laser operating circuit 1002, a signal generation circuit 1003, a servo circuit 1004 and a disc driving motor 1005, as shown in FIG. 15.

Record data S1 generated on the basis of data to be recorded in the optical disc DI is inputted in the controller 1001. The controller 1001 outputs a signal S2 to the laser operating circuit 1002 and outputs a signal S7 to the servo circuit 1004 in response to the record data S1 and a signal S5 from the signal generation circuit 1003 described later. The controller 1001 outputs playback data S10 on the basis of the signal S5, as described later. The laser operating circuit 1002 outputs a signal S3 controlling laser power emitted from the semiconductor laser apparatus 300 in the optical pickup 1000 in response to the aforementioned signal S2. In other words, the semiconductor laser apparatus 300 is driven by the controller 1001 and the laser operating circuit 1002.

In the optical pickup 1000, a laser beam controlled in response to the aforementioned signal S3 is applied to the optical disc DI. A signal S4 is output from the light detection portion 410 in the optical pickup 1000 to the signal generation circuit 1003. The optical system 400 (the actuator of the beam expander 403 and the objective lens actuator driving the objective lens 405) in the optical pickup 1000 is controlled by a servo signal S8 from the servo circuit 1004 described later. The signal generation circuit 1003 performs amplification and arithmetic processing for the signal S4 output from the optical pickup 1000, to output the first output signal S5 including a playback signal to the controller 1001 and to output a second output signal S6 performing the aforementioned feed-back control of the optical pickup 1000 and rotational control, described later, of the optical disc DI to the servo circuit 1004.

The servo circuit 1004 outputs the servo signal S8 controlling the optical system 400 in the optical pickup 1000 and a motor servo signal S9 controlling the disc driving motor 1005 in response to the control signals S6 and S7 from the signal generation circuit 1003 and the controller 1001. The disc driving motor 1005 controls a rotational speed of the optical disc DI in response to the motor servo signal S9.

When data recorded in the optical disc DI is play backed, a laser beam having a wavelength to be applied is first selected by means identifying types (CD, DVD, BD, etc.) of the optical disc DI, which is not described here. Then, the signal S2 is so output from the controller 1001 to the laser operating circuit 1002 that an intensity of the laser beam having the wavelength to be emitted from the semiconductor laser apparatus 300 in the optical pickup 1000 is constant. Further, the signal S4 including a playback signal is output from the light detection portion 410 to the signal generation circuit 1003 by functioning the semiconductor laser apparatus 300, the optical system 400 and the light detection portion 410 of the optical pickup 1000 as described in the third embodiment, and the signal generation circuit 1003 outputs the signal S5 including the playback signal to the controller 1001. The controller 1001 processes the signal S5, so that the playback signal recorded in the optical disc DI is extracted and output as the playback data S10. Information such as images and sound recorded in the optical disc DI can be output to a monitor, a speaker and the like with this playback data S10, for example. Feedback control of each portion is performed on the basis of the signal S4 from the light detection portion 410.

When data is recorded in the optical disc DI, the laser beam having the wavelength to be applied is selected by the means identifying types (CD, DVD, BD, etc.) of the optical disc DI, similarly to the above. Then, the signal S2 is output from the controller 1001 to the laser operating circuit 1002 in response to the record data S1 responsive to recorded data. Further, data is recorded in the optical disc DI by functioning the semiconductor laser apparatus 300, the optical system 400 and the light detection portion 410 of the optical pickup 1000 as described in the third embodiment, and feed-back control of each portion is performed on the basis of the signal S4 from the light detection portion 410.

Thus, record in the optical disc DI and playback can be performed with the optical disc apparatus 2000.

In the optical disc apparatus 2000, the aforementioned semiconductor laser apparatus 200 is mounted in the semiconductor laser apparatus 300 in the optical pickup 1000, and hence the optical pickup 1000 with high reliability can be easily downsized and the weight thereof can be easily reduced. Thus, according to this embodiment, the optical disc apparatus 2000 with high reliability, capable of reducing in size and weight can be easily obtained. The remaining effects of this optical disc apparatus 2000 are similar to those of the aforementioned optical pickup 1000.

Although the present invention has been described and illustrated in detail, it is clearly understood that the same is by way of illustration and example only and is not to be taken by way of limitation, the spirit and scope of the present invention being limited only by the terms of the appended claims.

For example, while the height of the red semiconductor laser device 20 or the red/infrared two-wavelength semiconductor laser device 30 from the upper surface 1a of the submount 1 is rendered larger than the height of the blue-violet semiconductor laser device 10 from the upper surface 1a of the submount 1 in each of the first and second embodiments, the present invention is not restricted to this but the height of the blue-violet semiconductor laser device 10 from the upper surface 1a of the submount 1 may be rendered larger than the height of the red semiconductor laser device 20 or the red/infrared two-wavelength semiconductor laser device 30 from the upper surface 1a of the submount 1.

GaN-based semiconductor constituting the blue-violet semiconductor laser device 10 is made of a harder material than GaInP-based semiconductor constituting the red semiconductor laser device 20 or GaAs-based semiconductor constituting the red/infrared two-wavelength semiconductor laser device 30. Therefore, a thickness of the n-type GaN substrate 11 of the blue-violet semiconductor laser device 10 is preferably rendered smaller than a thickness of the n-type GaAs substrate 21 of the red semiconductor laser device 20 or the n-type GaAs substrate 31 of the red/infrared two-wavelength semiconductor laser device 30 in order to easily carry out a cleavage step for forming a cavity facet. In this case, the thickness of the blue-violet semiconductor laser device 10 is smaller than the thickness of the red semiconductor laser device 20 or the red/infrared two-wavelength semiconductor laser device 30, and hence the height of the red semiconductor laser device 20 or the red/infrared two-wavelength semiconductor laser device 30 from the upper surface 1a of the submount 1 is preferably rendered larger than the height of the blue-violet semiconductor laser device 10 from the upper surface 1a of the submount 1.

While each semiconductor laser device is bonded onto the submount 1 in the junction-down manner in each of the aforementioned first and second embodiments, the present invention is not restricted to this. According to the present invention, a side, closer to the n-side electrode, of each semiconductor laser device may alternatively be bonded onto the submount 1 in a junction-up manner. Alternatively, one semiconductor laser device may be bonded in the junction-down manner and the other semiconductor laser device may be bonded in the junction-up manner.

While the red/infrared two-wavelength semiconductor laser device 30 is monolithically formed in each of the aforementioned second embodiment and modification thereof, the present invention is not restricted to this. The red semiconductor laser device and the infrared semiconductor laser device may alternatively be bonded to the submount 1 separately, for example. In other words, in this case, three semiconductor laser devices including the blue-violet semiconductor laser device 10 are bonded onto the submount 1 to be adjacent to each other. In this case, the bonded semiconductor laser devices are preferably bonded in increasing order of thickness.

While the blue-violet semiconductor laser device 10 and the red semiconductor laser device 20 or the red/infrared two-wavelength semiconductor laser device 30 are employed in each of the aforementioned first and second embodiments, the present invention is not restricted to this. In other words, a semiconductor laser device emitting a laser beam having another lasing wavelength can be employed. The semiconductor laser device may be made of another semiconductor material other than GaN-based semiconductor, GaInP-based semiconductor and GaAs-based semiconductor. Further, two semiconductor laser devices emitting laser beams having the same wavelength may be bonded to be adjacent to each other.

While the semiconductor laser apparatus 200 according to the aforementioned second embodiment is employed in each of the aforementioned third and fourth embodiments, the present invention is not restricted to this but the semiconductor laser apparatus 100 according to the aforementioned first embodiment may alternatively be employed.

While the aforementioned fourth embodiment has been described with reference to the optical disc apparatus 2000 as an example of the optical apparatus in the present invention, the present invention is not restricted to this but is also applicable to a display device such as a projector or a display. In this case, a semiconductor laser apparatus comprising a blue semiconductor laser device emitting a blue laser beam having a wavelength of about 440 nm, a green semiconductor laser device emitting a green laser beam having a wavelength of about 530 nm and a red semiconductor laser device emitting a red laser beam having a wavelength of about 635 nm may alternatively be employed as the semiconductor laser apparatus of the present invention employed as a light source for a display device. Alternatively, a blue/green semiconductor laser device integrally having a blue semiconductor laser device structure and a green semiconductor laser device structure in place of the blue semiconductor laser device and the green semiconductor laser device may be employed. In this case, heights of the blue semiconductor laser device, the green semiconductor laser device and the red semiconductor laser device (or the blue/green semiconductor laser device and the red semiconductor laser device) are preferably different from each other. Further, the melting point of a bonding layer bonding a high semiconductor laser device and the support member is preferably rendered lower than the melting point of a bonding layer bonding a low semiconductor laser device and the support member.

While the semiconductor laser apparatuses 100, 200 and 300 in which two semiconductor laser devices are bonded onto the submount 1 are employed in each of the aforementioned first to fourth embodiments, the present invention is not restricted to this. According to the present invention, more than two semiconductor laser devices may alternatively be bonded onto the support member similarly to the semiconductor laser apparatus in the display device described above. Also in this case, heights of the more than two semiconductor laser devices are preferably different from each other, and the melting point of a bonding layer bonding a high semiconductor laser device and the support member is preferably rendered lower than the melting point of a bonding layer bonding a low semiconductor laser device and the support member.

When bonding the first semiconductor laser device to the support member, the first semiconductor laser device may alternatively be bonded to the support member after placing the pellet on the support member in the second embodiment. At this time, the melting point of the pellet employed to bond the first semiconductor laser device is higher than the melting point of the pellet employed to bond the second semiconductor laser device. Thus, the pellet of the first bonded first semiconductor laser device can be inhibited from being remelted when bonding the second semiconductor laser device.

The “first bonding layer” and the “second bonding layer” in the present invention may be previously formed on the submount 1 before bonding the semiconductor laser device or may be formed on the semiconductor laser device before bonding. Alternatively, the “first bonding layer” and the “second bonding layer” in the present invention may be placed on the submount 1 in a state of pellets.

The “first semiconductor laser device” and the “second semiconductor laser device” in the present invention may be both multiple wavelength semiconductor laser devices.

The cross sections of the “first semiconductor laser device” and the “second semiconductor laser device” in the present invention may not be parallelogram shaped but may simply be formed such that the interval between the first and second semiconductor laser devices is narrow on the side closer to the submount 1 and becomes wider with increasing distance from the submount 1.

In the present invention, the “multiple wavelength semiconductor laser device” may not be formed on a common substrate. The “multiple wavelength semiconductor laser device” may have a structure in which the semiconductor laser devices are bonded to each other on a support substrate, for example.

The Au layer having a thickness of 3 μm located on the outermost surface of the p-side electrode 14 and the bonding layer 3 may not be alloyed with and completely integrated with each other in the aforementioned first embodiment. The Au layer and the bonding layer 3 may be partly alloyed with each other, and the Au layer may remain, for example.

What is claimed is:

1. A semiconductor laser apparatus comprising:
a support member having a main surface;
a first semiconductor laser device bonded onto said main surface through a first bonding layer; and
a second semiconductor laser device bonded onto said main surface through a second bonding layer, wherein
said first semiconductor laser device has a first surface and a second surface opposite to said first surface,
said second semiconductor laser device has a third surface and a fourth surface opposite to said third surface,
said second semiconductor laser device is arranged to be adjacent to said first semiconductor laser device,
said first surface of said first semiconductor laser device is bonded onto said main surface,
said third surface of said second semiconductor laser device is bonded onto said main surface,
the melting point of said second bonding layer is lower than that of said first bonding layer, and
a first height from said main surface to said fourth surface is larger than a second height from said main surface to said second surface.

2. The semiconductor laser apparatus according to claim 1, wherein
said first semiconductor laser device has a first semiconductor substrate on a side closer to said second surface and a first semiconductor device layer on a side closer to said first surface, and
said second semiconductor laser device has a second semiconductor substrate on a side closer to said fourth surface and a second semiconductor device layer on a side closer to said third surface.

3. The semiconductor laser apparatus according to claim 2, wherein
said first semiconductor laser device has a first electrode formed on said side closer to said first surface, and
said second semiconductor laser device has a second electrode formed on said side closer to said third surface.

4. The semiconductor laser apparatus according to claim 3, wherein
at least either said first electrode or said second electrode includes a multilayer structure in which a first Ti layer, an Au layer and a second Ti layer are arranged in this order from a side closer to said main surface.

5. The semiconductor laser apparatus according to claim 4, wherein
a thickness of said first Ti layer is larger than that of said second Ti layer.

6. The semiconductor laser apparatus according to claim 4, wherein
an ohmic electrode layer is arranged between said second Ti layer and at least either said first semiconductor device layer or said second semiconductor device layer.

7. The semiconductor laser apparatus according to claim 1, wherein
said first bonding layer includes Au and Sn,
said second bonding layer includes Au and Sn, and
a ratio of Au to Sn in said first bonding layer is larger than a ratio of Au to Sn in said second bonding layer.

8. The semiconductor laser apparatus according to claim 1, wherein
a thickness of said first bonding layer and a thickness of said second bonding layer are substantially equal to each other.

9. The semiconductor laser apparatus according to claim 1, wherein
said support member is a heat radiation substrate.

10. The semiconductor laser apparatus according to claim 1, wherein
at least either said first semiconductor laser device or said second semiconductor laser device is formed by a multiple wavelength semiconductor laser device emitting laser beams having lasing wavelengths different from each other.

11. The semiconductor laser apparatus according to claim 1, wherein
an interval between said first semiconductor laser device and said second semiconductor laser device is narrow on a side closer to said main surface and becomes wider with increasing distance from said main surface.

12. The semiconductor laser apparatus according to claim 11, wherein
a cross section of at least either said first semiconductor laser device or said second semiconductor laser device is substantially parallelogram shaped.

13. The semiconductor laser apparatus according to claim 10, wherein
said multiple wavelength semiconductor laser device has a common semiconductor substrate.

14. The semiconductor laser apparatus according to claim 1, wherein
one of either said first semiconductor laser device or said second semiconductor laser device is a nitride-based semiconductor laser device, and the other of either said first semiconductor laser device or said second semiconductor laser device is a GaInP-based semiconductor laser device or a GaAs-based semiconductor laser device.

15. A method of manufacturing a semiconductor laser apparatus comprising steps of:
bonding a first semiconductor laser device onto a main surface of a support member through a first bonding layer; and
bonding a second semiconductor laser device onto said main surface through a second bonding layer to be adjacent to said first semiconductor laser device after said step of bonding said first semiconductor laser device, wherein
said first semiconductor laser device has a first surface and a second surface opposite to said first surface,
said second semiconductor laser device has a third surface and a fourth surface opposite to said third surface,
said first surface of said first semiconductor laser device is bonded onto said main surface,
said third surface of said second semiconductor laser device is bonded onto said main surface, and
a first height from said main surface to said fourth surface is larger than a second height from said main surface to said second surface.

16. The method of manufacturing a semiconductor laser apparatus according to claim 15, wherein
the melting point of said second bonding layer is lower than the melting point of said first bonding layer, and
said step of bonding said second semiconductor laser device has heat treatment performed at a temperature lower than the melting point of said first bonding layer and higher than the melting point of said second bonding layer.

17. The method of manufacturing a semiconductor laser apparatus according to claim 15, further comprising a step of forming said first bonding layer on said main surface before said step of bonding said first semiconductor laser device, wherein
said step of bonding said first semiconductor laser device includes a step of bonding said first surface to said first bonding layer.

18. The method of manufacturing a semiconductor laser apparatus according to claim 15, further comprising a step of forming said second bonding layer on said third surface before said step of bonding said second semiconductor laser device, wherein
said step of bonding said second semiconductor laser device includes a step of bonding said second bonding layer to said main surface.

19. The method of manufacturing a semiconductor laser apparatus according to claim 15, further comprising a step of placing a pellet made of a bonding material on said main surface before said step of bonding said second semiconductor laser device, wherein
said step of bonding said second semiconductor laser device includes a step of pressing said second semiconductor laser device to said pellet.

20. An optical apparatus comprising:
a semiconductor laser apparatus; and
an optical system adjusting a laser beam emitted from said semiconductor laser apparatus, wherein
said semiconductor laser apparatus includes a support member having a main surface, a first semiconductor laser device bonded onto said main surface through a first bonding layer and a second semiconductor laser device bonded onto said main surface through a second bonding layer, wherein
said first semiconductor laser device has a first surface and a second surface opposite to said first surface,
said second semiconductor laser device has a third surface and a fourth surface opposite to said third surface,
said second semiconductor laser device is arranged to be adjacent to said first semiconductor laser device,
said first surface of said first semiconductor laser device is bonded onto said main surface,
said third surface of said second semiconductor laser device is bonded onto said main surface,
the melting point of said second bonding layer is lower than that of said first bonding layer, and
a first height from said main surface to said fourth surface is larger than a second height from said main surface to said second surface.
